(19) United States
(12) Patent Application Publication
(10) Pub. No.: US 2026/0239897 A1
(43) Pub. Date: Aug. 13, 2026

(54) FILM FORMING METHOD AND FILM FORMING APPARATUS

(71) Applicant: Tokyo Electron Limited, Tokyo (JP)

(72) Inventors: Ryunosuke HAYASHI, Yamanashi (JP); Tatsuya MIYAHARA, Yamanashi (JP)

(21) Appl. No.: 19/529,707

(22) Filed: Feb. 4, 2026

(30) Foreign Application Priority Data
Feb. 12, 2025 (JP) 2025-020813

(51) Int. Cl. H10P 14/20; C30B 29/06; H10D 30/01

(52) U.S. Cl. CPC H10P 14/3816; C30B 29/06; H10D 30/0316

(57) ABSTRACT

A film forming method includes preparing a substrate, forming an amorphous silicon film over the substrate, and crystallizing the amorphous silicon film. The forming of the amorphous silicon film includes supplying a first processing gas including a silicon-containing gas and a phosphorus-containing gas to the substrate, supplying a second processing gas including the silicon-containing gas and a carbon-containing gas to the substrate, and supplying a third processing gas including the silicon-containing gas and not including the phosphorus-containing gas and the carbon-containing gas to the substrate. The supplying of the first processing gas is performed at an initial stage of or at an intermediate stage of the forming of the amorphous silicon film.

### CROSS-REFERENCE TO RELATED APPLICATIONS

This application is based on and claims priority to Japanese Patent Application No. 2025-020813, filed on Feb. 12, 2025, the entire contents of which are incorporated herein by reference.

### TECHNICAL FIELD

The present disclosure relates to a film forming method and a film forming apparatus.

### BACKGROUND ART

Japanese Laid-Open Patent Publication No. 2021-106217 describes that a polycrystalline silicon film is formed by forming a stacked film in which an interface layer, a bulk layer, and a surface layer are stacked in this order on a base, and subsequently crystallizing the stacked film.

### SUMMARY

A film forming method according to one aspect of the present disclosure includes preparing a substrate, forming an amorphous silicon film over the substrate, and crystallizing the amorphous silicon film. The forming of the amorphous silicon film includes supplying a first processing gas including a silicon-containing gas and a phosphorus-containing gas to the substrate, supplying a second processing gas including the silicon-containing gas and a carbon-containing gas to the substrate, and supplying a third processing gas including the silicon-containing gas and not including the phosphorus-containing gas and the carbon-containing gas to the substrate. The supplying of the first processing gas is performed at an initial stage of or at an intermediate stage of the forming of the amorphous silicon film.

### BRIEF DESCRIPTION OF THE DRAWINGS

FIG. 1 is a flowchart illustrating a film forming method according to an embodiment;

FIG. 2 is a cross-sectional view (1) illustrating the film forming method according to the embodiment;

FIG. 3 is a cross-sectional view (2) illustrating the film forming method according to the embodiment;

FIG. 4 is a cross-sectional view (3) illustrating the film forming method according to the embodiment;

FIG. 5 is a cross-sectional view (4) illustrating the film forming method according to the embodiment;

FIG. 6 is a cross-sectional view (5) illustrating the film forming method according to the embodiment;

FIG. 7 is a diagram (1) illustrating a process of crystallizing an amorphous silicon film;

FIG. 8 is a diagram (2) illustrating a process of crystallizing an amorphous silicon film;

FIG. 9 is a vertical cross-sectional view illustrating a film forming apparatus according to the embodiment;

FIG. 10 is a horizontal cross-sectional view illustrating the film forming apparatus according to the embodiment;

FIG. 11 is a schematic diagram illustrating samples produced in an experiment;

FIG. 12 is a diagram (1) illustrating the grain sizes of polycrystalline silicon films; and

FIG. 13 is a diagram (2) illustrating the grain sizes of the polycrystalline silicon films.

### DETAILED DESCRIPTION

Non-limiting exemplary embodiments of the present disclosure will be described below with reference to the accompanying drawings. In all of the accompanying drawings, the same or corresponding members or parts are denoted by the same or corresponding reference numerals, and duplicated descriptions will be omitted.

### Film Forming Method

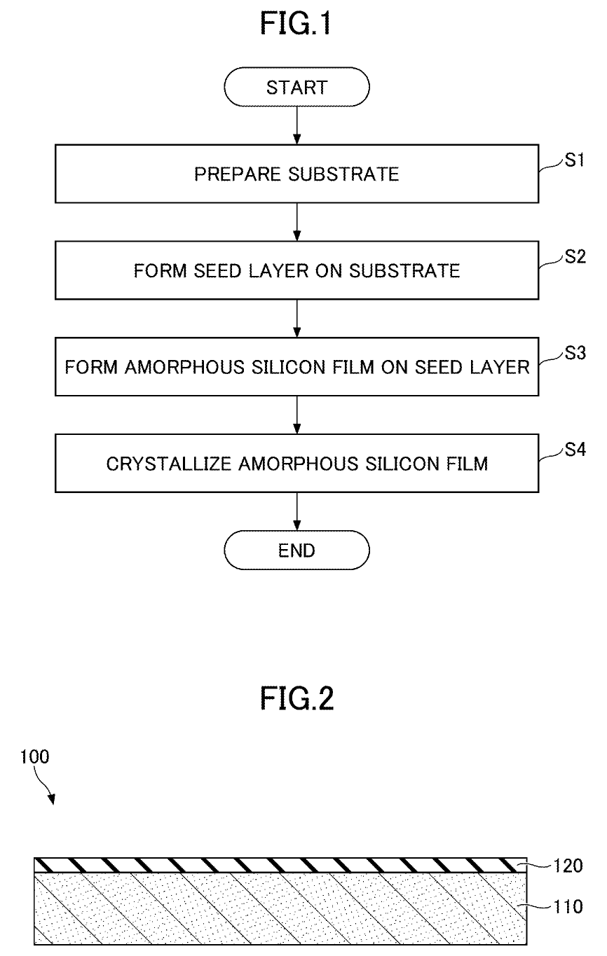

FIG. 1 is a flowchart illustrating a film forming method according to an embodiment. FIGS. 2 to 6 are cross-sectional views illustrating the film forming method according to the embodiment. The film forming method according to the embodiment includes step S1 to step S4 illustrated in FIG. 1.

In step S1, as illustrated in FIG. 2, a substrate 100 is prepared. The substrate 100 includes a base substrate 110 and an insulating film 120. The base substrate 110 is, for example, a silicon substrate. The insulating film 120 is provided at a surface of the substrate 100. The insulating film 120 is provided on the base substrate 110. The insulating film 120 is, for example, a silicon oxide film. The insulating film 120 may be a silicon nitride film or a silicon oxynitride film.

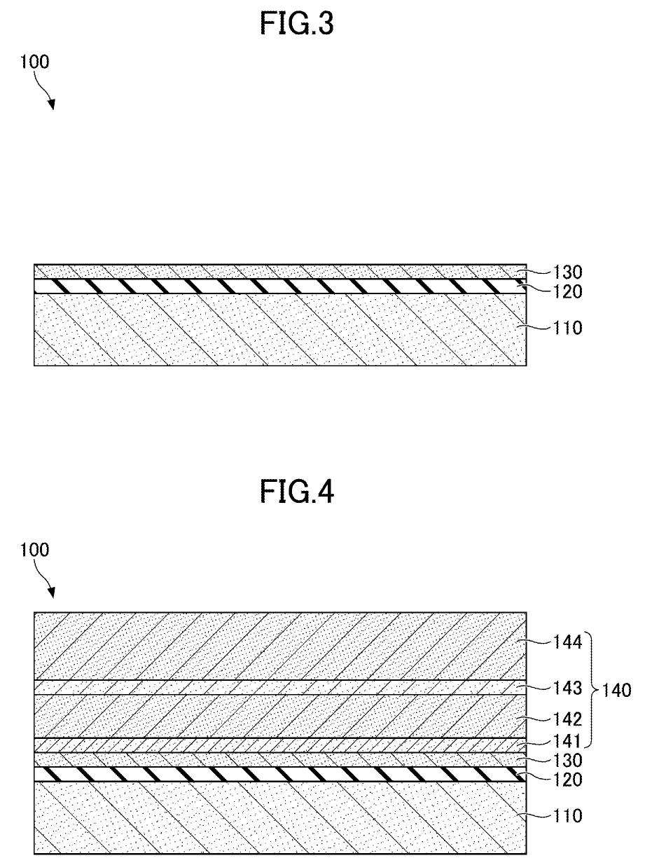

In step S2, as illustrated in FIG. 3, a seed layer 130 is formed on the insulating film 120. The seed layer 130 is a layer for facilitating the formation of an amorphous silicon film on the insulating film 120 in step S3. The seed layer 130 is, for example, a stacked film in which a first seed layer and a second seed layer are stacked in this order. The first seed layer can be formed, for example, by chemical vapor deposition (CVD) using an aminosilane-based gas. The aminosilane-based gas is, for example, di(isopropylamino)silane (DIPAS), tris(dimethylamino)silane (3DMAS), or bis(tert-butylamino)silane (BTBAS), or a combination thereof. The second seed layer can be formed, for example, by chemical vapor deposition using a high-order silane-based gas . The high-order silane-based gas refers to a silane-based gas containing two or more silicon (Si) atoms in one molecule. The high-order silane-based gas is, for example, disilane (Si₂H₆) gas, trisilane (Si₃H₈) gas, tetrasilane (Si₄H₁₀) gas, or a combination thereof. The seed layer 130 is not limited to the above-described stacked film. The seed layer 130 may be a monolayer film of the first seed layer. The seed layer 130 may be a monolayer film of the second seed layer.

In step S3, the amorphous silicon film is formed on the seed layer 130. As illustrated in FIG. 4, the amorphous silicon film may be a stacked film 140 in which an amorphous silicon film 141 doped with phosphorus (P), an amorphous silicon film 142 doped with no impurity, an amorphous silicon film 143 doped with carbon, and an amorphous silicon film 144 doped with no impurity are stacked in this order.

The amorphous silicon film 141 constitutes a lower surface of the stacked film 140. The amorphous silicon film 141 is in contact with the seed layer 130. The thickness of the amorphous silicon film 141 may be 1 nm or more and 3 nm or less, and is, for example, 2 nm. The amorphous silicon film 141 can be formed by chemical vapor deposition using a first processing gas including a silicon-containing gas and a phosphorus-containing gas.

The amorphous silicon film 142 is provided at an intermediate position of the stacked film 140 in the thickness direction. The amorphous silicon film 142 is in contact with the amorphous silicon film 141. The thickness of the amorphous silicon film 142 may be 3 nm or more and 8 nm or less, and is, for example, 5.5 nm. The amorphous silicon film 142 can be formed by chemical vapor deposition using a third processing gas including the silicon-containing gas and not including the phosphorus-containing gas and a carbon-containing gas.

The amorphous silicon film 143 is provided at an intermediate position of the stacked film 140 in the thickness direction. The amorphous silicon film 143 is in contact with the amorphous silicon film 142. The thickness of the amorphous silicon film 143 may be 1 nm or more and 3 nm or less, and is, for example, 2 nm. The amorphous silicon film 143 can be formed by chemical vapor deposition using a second processing gas including the silicon-containing gas and the carbon-containing gas.

The amorphous silicon film 144 constitutes an upper surface of the stacked film 140. The amorphous silicon film 144 is in contact with the amorphous silicon film 143. The thickness of the amorphous silicon film 144 may be 5 nm or more and 10 nm or less, and is, for example, 7.5 nm. The amorphous silicon film 144 can be formed by the same method as the amorphous silicon film 142.

In this manner, the stacked film 140 illustrated in FIG. 4 can be formed by performing chemical vapor deposition using the first processing gas at an initial stage, performing chemical vapor deposition using the second processing gas at an intermediate stage, and performing chemical vapor deposition using the third processing gas at a final stage of step S3. More specifically, the stacked film 240 illustrated in FIG. 4 can be formed by performing chemical vapor deposition using the first processing gas, chemical vapor deposition using the third processing gas, chemical vapor deposition using the second processing gas, and chemical vapor deposition using the third processing gas in this order.

As illustrated in FIG. 5, the amorphous silicon film may be a stacked film 240 in which an amorphous silicon film 241 doped with no impurity, an amorphous silicon film 242 doped with phosphorus and carbon, and an amorphous silicon film 243 doped with no impurity are stacked in this order.

The amorphous silicon film 241 constitutes a lower surface of the stacked film 240. The amorphous silicon film 241 is in contact with the seed layer 130. The thickness of the amorphous silicon film 241 may be 5 nm or more and 10 nm or less, and is, for example, 7.5 nm. The amorphous silicon film 241 can be formed by chemical vapor deposition using the third processing gas including the silicon-containing gas and not including the phosphorus-containing gas and the carbon- containing gas.

The amorphous silicon film 242 is provided at an intermediate position of the stacked film 240 in the thickness direction. The amorphous silicon film 242 is in contact with the amorphous silicon film 241. The thickness of the amorphous silicon film 242 may be 1 nm or more and 3 nm or less, and is, for example, 2 nm. The amorphous silicon film 242 can be formed by chemical vapor deposition using a fourth processing gas including the silicon-containing gas, the phosphorus-containing gas, and the carbon-containing gas.

The amorphous silicon film 243 constitutes an upper surface of the stacked film 240. The amorphous silicon film 243 is in contact with the amorphous silicon film 242. The thickness of the amorphous silicon film 243 may be 5 nm or more and 10 nm or less, and is, for example, 7.5 nm. The amorphous silicon film 243 can be formed by the same method as the amorphous silicon film 241.

In this manner, the stacked film 240 illustrated in FIG. 5 can be formed by performing chemical vapor deposition using the third processing gas at an initial stage, chemical vapor deposition using the fourth processing gas at an intermediate stage, and chemical vapor deposition using the third processing gas at a final stage of step S3. That is, the stacked film 240 illustrated in FIG. 5 can be formed by performing chemical vapor deposition using the third processing gas, chemical vapor deposition using the fourth processing gas, and chemical vapor deposition using the third processing gas in this order.

The silicon-containing gas is, for example, monosilane gas. The silicon-containing gas may be disilane gas, trisilane gas, or dichlorosilane gas. The phosphorus-containing gas is, for example, phosphine (PH₃) gas. The phosphorus-containing gas may be phosphorus trichloride gas. The carbon-containing gas is, for example, ethylene (C₂H₄) gas. The carbon-containing gas may be ethane gas, methane gas, acetylene gas, propane gas, propylene gas, butane gas, or butadiene gas.

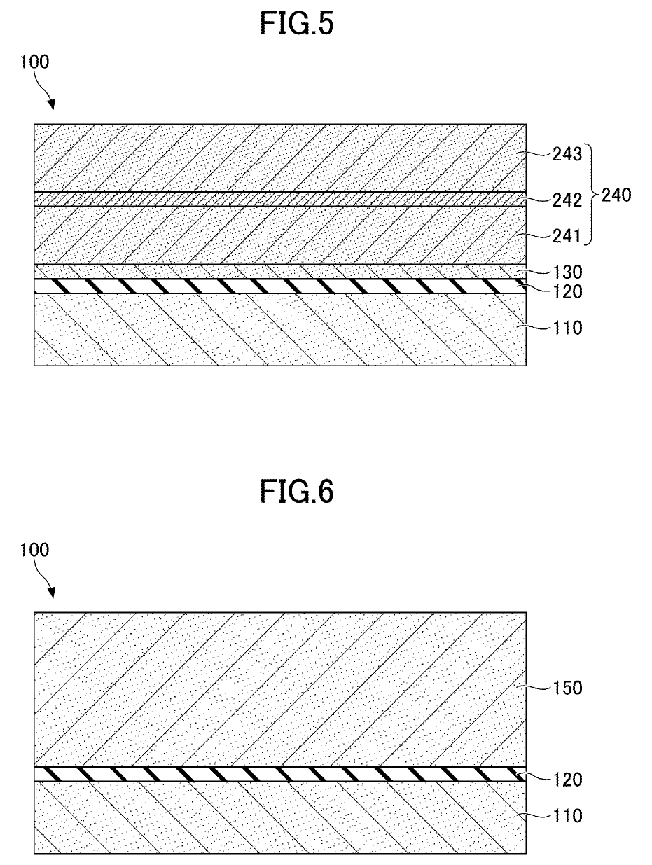

In step S4, the amorphous silicon film (the stacked film 140 or 240) formed in step S3 is crystallized by heat-treating the substrate 100. As a result, as illustrated in FIG. 6, a polycrystalline silicon film 150 is formed from the seed layer 130 and the amorphous silicon film (the stacked film 140 or 240). The atmosphere in which the substrate 100 is heat-treated in step S4, is, for example, an inert gas atmosphere at atmospheric pressure. The inert gas is not particularly limited and is, for example, nitrogen (N₂) gas. The atmosphere in which the substrate 100 is heat- treated may be a reduced pressure atmosphere.

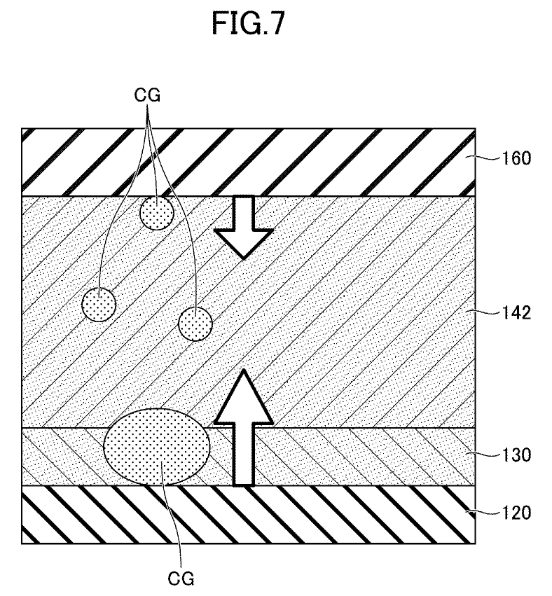

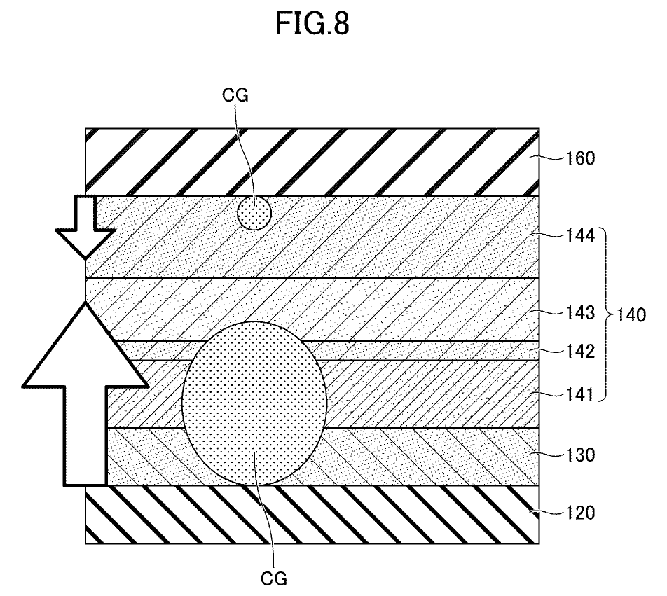

FIGS. 7 and 8 are diagrams each illustrating a process of crystallizing an amorphous silicon film. In FIGS. 7 and 8, crystal grains CG are schematically illustrated.

As illustrated in FIG. 7, a case will be considered in which a substrate, in which a seed layer 130, an amorphous silicon film 142 doped with no impurity, and a native oxide film 160 are stacked in this order on an insulating film 120, is heat-treated. In this case, crystal growth of the amorphous silicon film 142 from the seed layer 130 side is dominant over crystal growth of the amorphous silicon film 142 from the native oxide film 160 side. However, crystal nuclei are also generated in the amorphous silicon film 142. The crystal nuclei generated in the amorphous silicon film 142 inhibit the crystal growth of the amorphous silicon film 142 from the seed layer 130 side.

As illustrated in FIG. 8, a case is considered in which a substrate, in which a seed layer 130, an amorphous silicon film 141 doped with phosphorus, an amorphous silicon film 142 doped with no impurity, an amorphous silicon film 143 doped with carbon, an amorphous silicon film 144 doped with no impurity, and a native oxide film 160 are stacked in this order on an insulating film 120, is heat-treated. The amorphous silicon film 141 doped with phosphorus has a property of promoting crystallization. Therefore, crystallization of the stacked film 140 from the seed layer 130 side is promoted. As a result, the dominance of crystal growth of the stacked film 140 from the seed layer 130 side over crystal growth of the stacked film 140 from the native oxide film 160 side is greater than that in a case where the amorphous silicon film 141 is not provided. The amorphous silicon film 143 doped with carbon has a property of suppressing generation of crystal nuclei. Therefore, generation of crystal nuclei in the stacked film 140 is suppressed. Thus, the crystal growth of the stacked film 140 from the seed layer 130 side is less likely to be inhibited. As a result, the grain size of a polycrystalline silicon film 150 can be increased as compared to a case where the amorphous silicon film 141 and the amorphous silicon film 143 are not provided.

As described above, according to the film deposition method according to the embodiment, after the stacked film 140 or 240 is formed on the seed layer 130 in step S3, the stacked film 140 or 240 is crystallized through heat treatment in step S4. The stacked film 140 includes the amorphous silicon film 141 doped with phosphorus, the amorphous silicon film 143 doped with carbon, and the amorphous silicon films 142 and 144 doped with no impurity, and the stacked film 240 includes the amorphous silicon film 242 doped with phosphorus and carbon and the amorphous silicon films 241 and 243 doped with no impurity. The amorphous silicon film 141 doped with phosphorus constitutes the lower surface of the stacked film 140. The amorphous silicon film 242 doped with phosphorus is provided at an intermediate position of the stacked film 240. In any of these cases, crystal growth of the stacked film 140 or 240 from the seed layer 130 side is dominant, and generation of crystal nuclei in the stacked film 140 or 240 is suppressed. As a result, the grain size of the polycrystalline silicon film 150 can be increased.

### Film Forming Apparatus

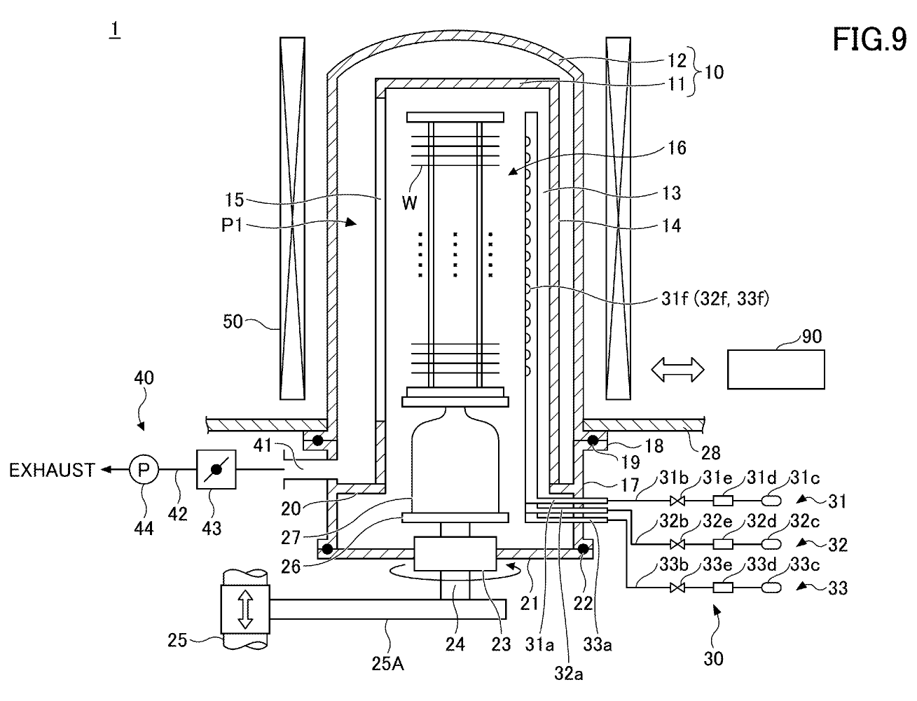

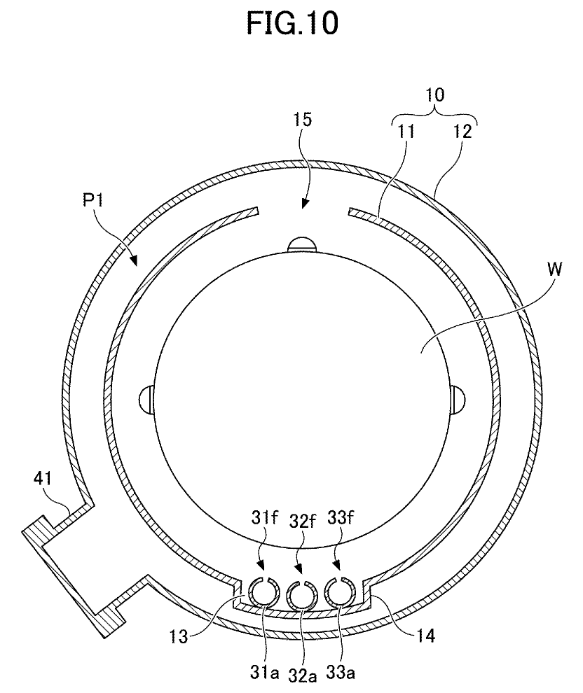

FIG. 9 is a vertical cross-sectional view illustrating a film forming apparatus 1 according to the embodiment. FIG. 10 is a horizontal cross-sectional view illustrating the film forming apparatus 1 according to the embodiment.

The film forming apparatus 1 is a batch-type apparatus that simultaneously performs processes on a plurality of substrates W. The substrates W are, for example, semiconductor wafers. The film forming apparatus 1 includes a processing chamber 10, a gas supply 30, an exhaust 40, a heater 50, and a controller 90.

The inside of the processing chamber 10 can be depressurized. The processing chamber 10 accommodates the substrates W. The processing chamber 10 includes an inner tube 11 and an outer tube 12. The inner tube 11 has a cylindrical shape with a ceiling and an open lower end. The outer tube 12 has a cylindrical shape with a ceiling and an open lower end and covers the outer side of the inner tube 11. The inner tube 11 and the outer tube 12 are formed of a heat resistant material such as quartz. The inner tube 11 and the outer tube 12 are arranged to be concentric to form a double-tube structure.

An accommodating section 13 for accommodating gas nozzles along the longitudinal direction (vertical direction) of the inner tube 11 is formed on the side wall of the inner tube 11. For example, the side wall of the inner tube 11 partially protrudes outward to form a protrusion 14, and the inner space of the protrusion 14 is formed as the accommodating section 13.

A rectangular opening 15 is formed in the side wall of the inner tube 11 along the longitudinal direction of the inner tube 11. The opening 15 faces the accommodating section 13.

The opening 15 is a gas exhaust port configured to exhaust the gas that is in the inner tube 11. The length of the opening 15 is the same as the length of a boat 16. Alternatively, the length of the opening 15 is greater than the length of the boat 16 so that the opening 15 extends further in the vertical direction than the boat 16.

The lower end of the processing chamber 10 is supported by a cylindrical manifold 17. The manifold 17 is formed of, for example, stainless steel. A flange 18 is formed on the upper end of the manifold 17. The flange 18 supports the lower end of the outer tube 12. A seal member 19 such as an O-ring is provided between the flange 18 and the lower end of the outer tube 12. Thus, the inside of the outer tube 12 is maintained airtight.

An annular support 20 is provided on the inner wall at an upper portion of the manifold 17. The support 20 supports the lower end of the inner tube 11. A lid 21 is airtightly attached to an opening at the lower end of the manifold 17 via a seal member 22 such as an O-ring. Thus, the opening at the lower end of the processing chamber 10, that is, the opening of the manifold 17, is closed airtight. The lid 21 is formed of, for example, stainless steel.

A rotating shaft 24 is provided so as to penetrate a center portion of the lid 21 via a magnetic fluid seal 23. A lower portion of the rotating shaft 24 is rotatably supported on an arm 25A of an elevator mechanism 25 including a boat elevator.

A rotary plate 26 is provided on the upper end of the rotating shaft 24. The boat 16 configured to hold the substrates W via a thermal insulation base 27 formed of quartz is placed on the rotary plate 26. By rotating the rotating shaft 24, the boat 16 rotates. By raising and lowering the elevator mechanism 25, the boat 16 moves up and down integrally with the lid 21. Thus, the boat 16 is inserted into and removed from the processing chamber 10. The boat 16 can be accommodated inside the processing chamber 10. The boat 16 holds the plurality of (for example, 50 to 150) substrates W at intervals in a vertically stacked manner. The boat 16 holds the plurality of substrates W in an approximately horizontal state at intervals in the vertical direction.

The gas supply 30 is configured to introduce various processing gases into the inner tube 11. The gas supply 30 includes a silicon source supply 31, a phosphorus source supply 32, and a carbon source supply 33.

The silicon source supply 31 includes a gas supply pipe 31a inside the processing chamber 10, and a supply passage 31b outside the processing chamber 10. The supply passage 31b is provided with a silicon source 31c, a mass flow controller 31d, and a valve 31e in this order from the upstream side to the downstream side along a gas flowing direction. A supply timing of the silicon- containing gas from the silicon source 31c is controlled by the valve 31e, and the flow rate of the silicon-containing gas is adjusted to a predetermined flow rate by the mass flow controller 31d. The silicon-containing gas flows from the supply passage 31b to the gas supply pipe 31a, and is discharged from the gas supply pipe 31a into the processing chamber 10.

The phosphorus source supply 32 includes a gas supply pipe 32a inside the processing chamber 10, and a supply passage 32b outside the processing chamber 10. The supply passage 32b is provided with a phosphorus source 32c, a mass flow controller 32d, and a valve 32e in this order from the upstream side to the downstream side along a gas flowing direction. A supply timing of the phosphorus-containing gas from the phosphorus source 32c is controlled by the valve 32e, and the flow rate of the phosphorus-containing gas is adjusted to a predetermined flow rate by the mass flow controller 32d. The phosphorus-containing gas flows from the supply passage 32b to the gas supply pipe 32a, and is discharged from the gas supply pipe 32a into the processing chamber 10.

The carbon source supply 33 includes a gas supply pipe 33a inside the processing chamber 10, and a supply passage 33b outside the processing chamber 10. The supply passage 33b is provided with a carbon source 33c, a mass flow controller 33d, and a valve 33e in this order from the upstream side to the downstream side along a gas flowing direction. A supply timing of the carbon-containing gas from the carbon source 33c is controlled by the valve 33e, and the flow rate of the carbon-containing gas is adjusted to a predetermined flow rate by the mass flow controller 33d. The carbon-containing gas flows from the supply passage 33b to the gas supply pipe 33a, and is discharged from the gas supply pipe 33a into the processing chamber 10.

Each of the gas supply pipes 31a, 32a, and 33a is fixed to the manifold 17. Each of the gas supply pipes 31a, 32a, and 33a is formed of, for example, quartz. Each of the gas supply pipes 31a, 32a, and 33a extends linearly along the vertical direction at a position near the inner tube 11, and is bent in an L shape inside the manifold 17 to extend in the horizontal direction so as to penetrate the manifold 17. The gas supply pipes 31a, 32a, and 33a are arranged in the circumferential direction of the inner tube 11, and are formed at the same height.

A plurality of discharge ports 31f, 32f, and 33f are provided in respective portions of the gas supply pipes 31a, 32a, and 33a located inside the inner tube 11. The discharge ports 31f, 32f, and 33f are formed at predetermined intervals along the extending direction of the gas supply pipes 31a, 32a, and 33a. The discharge ports 31f, 32f, and 33f horizontally discharge gas toward the substrates W from the outer side in the radial direction of the substrates W. The discharge ports 31f, 32f, and 33f discharge gas parallel to the main surfaces of the substrates W. The interval between adjacent discharge ports is set to be the same as the interval between adjacent substrates W held by the boat 16, for example. The position of each discharge port in the height direction is set to an intermediate position between the adjacent substrates W that are adjacent to each other in the vertical direction. In this case, each discharge port can efficiently supply gas to the facing surfaces of the adjacent substrates W.

The gas supply 30 may mix a plurality of kinds of gases and discharge the mixed gas from a single gas supply pipe. The gas supply pipes 31a, 32a, and 33a may have mutually different shapes and arrangements. The gas supply 30 may further include a gas supply pipe configured to supply a different kind of gas, for example, an inert gas.

The exhaust 40 exhausts gas that flows from the inner tube 11 through the opening 15, travels through a space P1 between the inner tube 11 and the outer tube 12, and is discharged via a gas outlet 41. The gas outlet 41 is formed in the side wall at an upper portion of the manifold 17 above the support 20. An exhaust passage 42 is connected to the gas outlet 41. A pressure regulating valve 43 and a vacuum pump 44 are successively provided in the exhaust passage 42, so that the gas inside the processing chamber 10 can be exhausted.

The heater 50 is provided around the outer tube 12. The heater 50 is provided, for example, on a base plate 28. The heater 50 has a cylindrical shape so as to cover the outer tube 12. The heater 50 includes, for example, a heating element, and heats each of the substrates W inside the processing chamber 10.

The controller 90 is an electronic circuit such as a central processing unit (CPU), a field programmable gate array (FPGA), or an application specific integrated circuit (ASIC). The controller 90 performs various control operations described in the present specification by executing instruction codes stored in a memory or by being designed as a circuit for a special application.

### Operation of Film Forming Apparatus

The operation of the film forming apparatus 1 when the film forming apparatus 1 performs the film forming method according to the embodiment will be described. The operation of the film forming apparatus 1 described below is performed as controlled by the controller 90.

First, the elevator mechanism 25 loads the boat 16 holding the plurality of substrates W into the processing chamber 10, and the lid 21 closes the opening at the lower end of the processing chamber 10 to seal the processing chamber 10 airtight. Then, the exhaust 40 depressurizes the inside of the processing chamber 10, and the heater 50 adjusts the temperature of the substrates W to a predetermined temperature. Each of the substrates W may be the substrate 100 described above.

Next, the controller 90 controls the gas supply 30, the exhaust 40, and the heater 50 to perform step S2, step S3, and step S4 of the film forming method according to the embodiment in this order.

Next, the controller 90 raises the pressure inside the processing chamber 10 to the atmospheric pressure and lowers the temperature inside the processing chamber 10 to an unloading temperature, and then controls the elevator mechanism 25 to unload the boat 16 from the processing chamber 10.

### Experimental Results

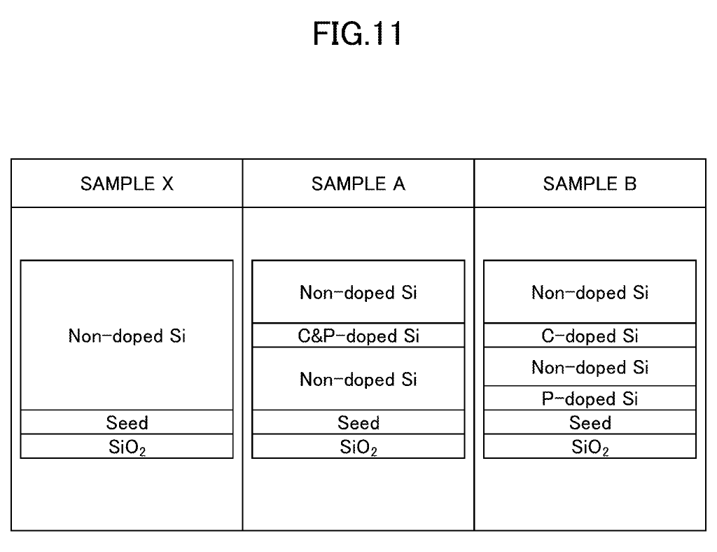

FIG. 11 is a schematic diagram illustrating samples produced in an experiment. In FIG. 11, a silicon oxide film, which is an example of an insulating film, is denoted by “SiO₂”, and a seed layer is denoted by “seed”. Further, an amorphous silicon film doped with phosphorus is denoted by “P-doped Si”, an amorphous silicon film doped with carbon is denoted by “C-doped Si”, and an amorphous silicon film doped with phosphorus and carbon is denoted by “C & P-doped Si”. Further, an amorphous silicon film doped with no impurity is denoted by “non-doped Si”.

In the experiment, samples X, A, and B illustrated in FIG. 11 were produced.

The sample X had a stacked structure in which a silicon oxide film, a seed layer, and an amorphous silicon film doped with no impurity were stacked in this order. The thickness of the seed layer was 2 nm. The thickness of the amorphous silicon film doped with no impurity was 17 nm.

The sample A had a stacked structure in which a silicon oxide film, a seed layer, an amorphous silicon film doped with no impurity, an amorphous silicon film doped with phosphorus and carbon, and an amorphous silicon film doped with no impurity were stacked in this order. The thickness of the seed layer was 2 nm. The thickness of each of the amorphous silicon films doped with no impurity was 7.5 nm. The thickness of the amorphous silicon film doped with phosphorus and carbon was 2 nm. The peak value of the phosphorus concentration of the amorphous silicon film doped with phosphorus and carbon was 1 × 10²¹ cm⁻³. The peak value of the carbon concentration of the amorphous silicon film doped with phosphorus and carbon was 8 × 10²⁰ cm⁻³.

The sample B had a stacked structure in which a silicon oxide film, a seed layer, an amorphous silicon film doped with phosphorus, an amorphous silicon film doped with no impurity, an amorphous silicon film doped with carbon, and an amorphous silicon film doped with no impurity were stacked in this order. The thickness of the seed layer was 2 nm. The thickness of the amorphous silicon film doped with phosphorus was 2 nm. The thickness of the amorphous silicon film doped with no impurity, located between the amorphous silicon film doped with phosphorus and the amorphous silicon film doped with carbon, was 5.5 nm. The thickness of the amorphous silicon film doped with carbon was 2 nm. The thickness of the amorphous silicon film doped with no impurity, located on the amorphous silicon film doped with carbon, was 7.5 nm. The peak value of the phosphorus concentration of the amorphous silicon film doped with phosphorus was 1 × 10²¹ cm⁻³. The peak value of the carbon concentration of the amorphous silicon film doped with carbon was 8 × 10²⁰ cm⁻³.

Next, the sample X, the sample A, and the sample B were heat-treated at 620° C for 36 hours in a nitrogen gas atmosphere at atmospheric pressure to crystallize the amorphous silicon films and form polycrystalline silicon films. Next, grain maps of the polycrystalline silicon films of the sample X, the sample A, and the sample B were obtained by electron backscatter diffraction (EBSD). Further, based on the grain maps, weighted average grain sizes and average grain sizes were calculated.

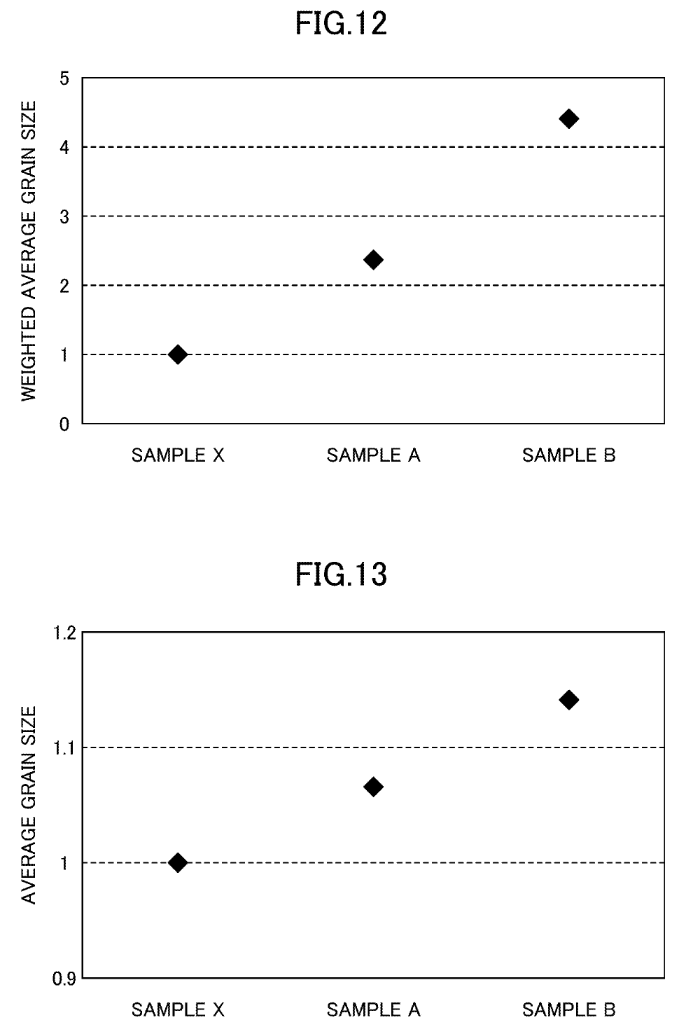

FIGS. 12 and 13 are diagrams illustrating the grain sizes of the polycrystalline silicon films. FIG. 12 illustrates relative values of the weighted average grain sizes of the polycrystalline silicon films of the sample A and the sample B, where the weighted average grain size of the polycrystalline silicon film of the sample X is defined as 1. FIG. 13 illustrates relative values of the average grain sizes of the polycrystalline silicon films of the sample A and the sample B, where the average grain size of the polycrystalline silicon film of the sample X is defined as 1.

As illustrated in FIG. 12, the weighted average grain size of the polycrystalline silicon film of the sample A is about 2.4 times the weighted average grain size of the polycrystalline silicon film of the sample X. As illustrated in FIG. 13, the average grain size of the polycrystalline silicon film of the sample A is about 1.06 times the average grain size of the polycrystalline silicon film of the sample X. From these results, it can be said that the grain size of the polycrystalline silicon film can be increased by providing the amorphous silicon film doped with phosphorus and carbon at an intermediate position of the stacked structure in the thickness direction, as compared to a case where the amorphous silicon film doped with phosphorus and carbon is not provided.

As illustrated in FIG. 12, the weighted average grain size of the polycrystalline silicon film of the sample B is about 4.4 times the weighted average grain size of the polycrystalline silicon film of the sample X. As illustrated in FIG. 13, the average grain size of the polycrystalline silicon film of the sample B is about 1.14 times the average grain size of the polycrystalline silicon film of the sample X. From these results, it can be said that the grain size of the polycrystalline silicon film can be particularly increased by providing the amorphous silicon film doped with phosphorus in contact with the seed layer and providing the amorphous silicon film doped with carbon at an intermediate position of the stacked structure in the thickness direction.

While certain embodiments have been described, these embodiments have been presented by way of example only, and are not intended to limit the scope of the present disclosure. Indeed, the embodiments described herein may be embodied in a variety of other forms. Furthermore, various omissions, substitutions and changes in the form of the embodiments described herein may be made without departing from the spirit of the present disclosure.

In the above-described embodiments, an example in which the film forming apparatus is a batch-type apparatus configured to process a plurality of substrates at one time has been described; however, the present disclosure is not limited thereto. For example, the film forming apparatus may be a single-wafer type apparatus configured to process substrates one by one. For example, the film forming apparatus may be a semi-batch-type apparatus configured to process a plurality of substrates disposed on a rotation table by rotating the rotation table to allow each of the substrates to revolve and repeatedly pass through processing gas supply regions disposed along the radius direction of the rotation table.

According to an embodiment of the present disclosure, the grain size of a polycrystalline silicon film can be increased.

What is claimed is:

1. A film forming method comprising:
preparing a substrate;
forming an amorphous silicon film over the substrate; and
crystallizing the amorphous silicon film, wherein
the forming of the amorphous silicon film includes
supplying a first processing gas including a silicon-containing gas and a phosphorus-containing gas to the substrate,
supplying a second processing gas including the silicon-containing gas and a carbon-containing gas to the substrate, and
supplying a third processing gas including the silicon-containing gas and not including the phosphorus-containing gas and the carbon-containing gas to the substrate, and
the supplying of the first processing gas is performed at an initial stage of or at an intermediate stage of the forming of the amorphous silicon film.

2. The film forming method according to claim 1, wherein the supplying of the second processing gas is performed at an intermediate stage of the forming of the amorphous silicon film.

3. The film forming method according to claim 1, wherein the supplying of the second processing gas is performed after the supplying of the first processing gas.

4. The film forming method according to claim 1, wherein the supplying of the second processing gas is performed concurrently with the supplying of the first processing gas.

5. The film forming method according to claim 1, wherein the supplying of the third processing gas is performed at a final stage of the forming of the amorphous silicon film.

6. The film forming method according to claim 1, wherein the supplying of the first processing gas, the supplying of the third processing gas, the supplying of the second processing gas, and the supplying of the third processing gas are performed in this order.

7. The film forming method according to claim 1, wherein the supplying of the third processing gas, the supplying of the first processing gas concurrently with the supplying of the second processing gas, and the supplying of the third processing gas are performed in this order.

8. The film forming method according to claim 1, further comprising:
forming a seed layer on the substrate before the forming of the amorphous silicon film.

9. The film forming method according to claim 1, wherein
the silicon-containing gas is monosilane gas,
the phosphorus-containing gas is phosphine gas, and
the carbon-containing gas is ethylene gas.

10. The film forming method according to claim 1, wherein the substrate includes a silicon oxide film at a surface of the substrate.

11. A film forming apparatus comprising:
a processor; and
a controller, wherein
the controller is configured to control the processor to execute
preparing a substrate,
forming an amorphous silicon film over the substrate, and
crystallizing the amorphous silicon film, wherein
the forming of the amorphous silicon film includes
supplying a first processing gas including a silicon-containing gas and a phosphorus-containing gas to the substrate,
supplying a second processing gas including the silicon-containing gas and a carbon-containing gas to the substrate, and
supplying a third processing gas including the silicon-containing gas and not including the phosphorus-containing gas and the carbon-containing gas to the substrate, and
the supplying of the first processing gas is performed at an initial stage of or at an intermediate stage of the forming of the amorphous silicon film.
